(19) United States
(12) Patent Application Publication
(10) Pub. No.: US 2007/0042512 A1
(43) Pub. Date: Feb. 22, 2007

(54) Apparatus and method of predicting performance of semiconductor manufacturing process and semiconductor device, and manufacturing method of semiconductor device

(76) Inventor: Kenji Kawabata, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/504,048

(22) Filed: Aug. 15, 2006

(30) Foreign Application Priority Data
Aug. 16, 2005 (JP) 2005-235970

(51) Int. Cl. H01L 21/66

(52) U.S. Cl. 438/14

(57) ABSTRACT

Apparatus and method of predicting performance of a semiconductor manufacturing process and device, which reduces simulation resources to predict the performance distribution in the wafer and manufacturing method of a semiconductor device are disclosed. According to one aspect, it is provided a performance prediction apparatus comprising a uniform mesh data generator generating uniform mesh data by dividing a wafer using a uniform mesh to predict an in-plane characteristics distribution of performance in a series of process steps, a non-uniform mesh generator generating a non-uniform mesh by combining element meshes based on the uniform mesh data and predetermined threshold, a common mesh generator generating a common mesh by superimposing the non-uniform meshes and selecting a minimum mesh by region, a common mesh data generator generating common mesh data by representing the performance using the common mesh, and a predicting section predicting a comprehensive performance after processing the series of processes.

### CROSS-REFERENCE TO RELATED APPLICATIONS

This application is based upon and claims the benefit of priority from prior Japanese Patent Application No. 2005-235970, filed Aug. 16, 2005, the entire contents of which are incorporated herein by reference.

### BACKGROUND OF THE INVENTION

1. Field of the Invention

The present invention relates to a characteristics distribution simulation technique in a wafer, and more particularly to apparatus and method of predicting performance in a wafer of a semiconductor manufacturing process and a semiconductor device by using an in-plane characteristics distribution simulation, and a manufacturing method of a semiconductor device.

2. Description of the Related Art In a semiconductor manufacturing process, an in-plane characteristics distribution simulation which predicts a performance of process and device in an entire wafer is carried out. In a current semiconductor manufacturing process, a performance and/or yield of process or device is considerably dependent on a variation of characteristics in a wafer in each process. Therefore, in the in-plane characteristics distribution simulation, it is important to consider a characteristics distribution in a wafer in every process.

In a conventional in-plane characteristics distribution simulation, uniform mesh data obtained by dividing a wafer surface by a uniform mesh is used as input data to perform a through-simulation, and a performance of a final product is predicted to every region divided by the uniform mesh. However, in the technique dividing the wafer surface by the uniform mesh, if a wafer is divided by a small uniform mesh in order to enhance a prediction accuracy, the number of uniform element meshes is increased. Therefore, a calculation amount and a calculation time required for the in-plane characteristics distribution simulation are increased.

Further, a mesh generation method to a semiconductor device structure is disclosed in, e.g., Jpn. Pat. Appln. KOKAI Publication No. 5-136267. However, a mesh generation technique for an in-plane characteristics distribution simulation is not discussed, and a performance of a process and a device in a wafer cannot be acquired.

### BRIEF SUMMARY OF THE INVENTION

According to one aspect of the present invention, it is provided a performance prediction apparatus comprising: a uniform mesh data generator generating uniform mesh data by dividing a wafer surface using a uniform mesh to predict an in-plane characteristics distribution of performance with respect to each of a series of process steps; a non-uniform mesh generator generating a non-uniform mesh which non-uniformly divides the wafer surface by combining a plurality of element meshes in the uniform mesh based on the uniform mesh data and predetermined threshold values with respect to each of the series of process steps; a common mesh generator generating a common mesh by superimposing the plurality of non-uniform meshes and selecting a minimum mesh from the non-uniform meshes for every region in the wafer; a common mesh data generator generating common mesh data by representing the in-plane characteristics distribution of performance with regard to each of the series of process steps using the common mesh; and a predicting section predicting a comprehensive performance after processing the series of process steps for every region divided by the common mesh based on the plurality of the common mesh data.

According to another aspect of the present invention, it is provided a performance predicting method comprising: generating uniform mesh data by dividing a wafer surface using a uniform mesh and predicting an in-plane characteristics distribution of performance with respect to each of a series of process steps; generating a non-uniform mesh which non-uniformly divides the wafer surface by combining a plurality of element meshes in the uniform mesh based on the uniform mesh data and predetermined threshold values with respect to each of the series of process steps; generating a common mesh by superimposing the plurality of non-uniform meshes and selecting a mesh having a minimum size from the non-uniform meshes for every region in the wafer; generating a common mesh data by representing the in-plane characteristics distribution of performance of each of the series of process steps using the common mesh; and predicting a comprehensive performance, which is a performance after processing through the series of process steps, for every region divided by the common mesh based on the common mesh data.

According to another aspect of the present invention, it is provided a manufacturing method of a semiconductor device comprising: using a performance prediction apparatus to generate uniform mesh data by dividing a wafer surface using a uniform mesh and predicting an in-plane characteristics distribution of performance with respect to each of a series of process steps, to generate a non-uniform mesh which non-uniformly divides the wafer surface by combining a plurality of element meshes in the uniform mesh based on the uniform mesh data and predetermined threshold values with respect to each of the series of process steps, to generate a common mesh by superimposing the plurality of non-uniform meshes and selecting a mesh having a minimum size from the non-uniform meshes for every region in the wafer, to generate a common mesh data by representing the in-plane characteristics distribution of performance of each of the series of process steps using the common mesh, and predicting a comprehensive performance, which is a performance after processing through the series of process steps, for every region divided by the common mesh based on the common mesh data; correcting process conditions of the series of process steps based on the comprehensive performance predicted by the performance prediction apparatus; and executing the series of process steps according to the corrected process conditions using a corresponding group of semiconductor manufacturing equipments to process a wafer.

### BRIEF DESCRIPTION OF THE SEVERAL VIEWS OF THE DRAWINGS

FIG. 1 is a block diagram showing an example of a performance prediction apparatus according to an embodiment of the present invention;

FIG. 2 is a flowchart showing an example of a series of process steps in manufacturing a semiconductor device according to an embodiment of the present invention;

FIGS. 3A to 3D show examples of process cross-sectional views of the semiconductor device in the series of manufacturing process steps depicted in FIG. 2;

FIG. 4 is a diagram showing an example of uniform mesh data of a film deposition process according to the embodiment of the present invention;

FIG. 5 is a diagram showing an example of uniform mesh data of a CMP process according to the embodiment of the present invention;

FIG. 6 is a diagram showing an example of uniform mesh data of an etching process according to the embodiment of the present invention;

FIG. 7 shows a diagram showing an example of a film thickness distribution along a wafer diameter to explain determination of a uniform mesh size according to the embodiment of the present invention;

FIG. 8 is a histogram showing an example of variation in a film thickness for each uniform mesh in the film deposition process according to the embodiment of the present invention;

FIG. 9 is a histogram showing an example of variation in reduction in film thickness for each uniform mesh in the CMP process according to the embodiment of the present invention;

FIG. 10 is a histogram showing an example of variation in an etching removal for each uniform mesh in the etching process according to the embodiment of the present invention;

FIG. 11 is a diagram showing an example of a non-uniform mesh for the film deposition process according to the embodiment of the present invention;

FIG. 12 is a diagram showing an example of another non-uniform mesh for the CMP process according to the embodiment of the present invention;

FIG. 13 is a diagram showing an example of another non-uniform mesh for the etching process according to the embodiment of the present invention;

FIG. 14 is a flowchart illustrating an example of a non-uniform mesh generating procedure according to an embodiment of the present invention;

FIGS. 15A and 15B are diagrams showing an example of data in an element mesh used in the non-uniform mesh generating procedure depicted in FIG. 14;

FIG. 16 is a diagram illustrating an example of a decision on combining element meshes used in the non-uniform mesh generating procedure depicted in FIG. 14;

FIG. 17 is a diagram illustrating an example of combining of element meshes in the non-uniform mesh generating procedure depicted in FIG. 14;

FIG. 18 is a diagram showing an example of a common mesh according to the embodiment of the present invention;

FIG. 19 is a diagram showing an example of common mesh data of the film deposition process according to the embodiment of the present invention;

FIG. 20 is a diagram showing an example of the common mesh data of the CMP process according to the embodiment of the present invention;

FIG. 21 is a diagram showing an example of the common mesh data of the etching process according to the embodiment of the present invention;

FIG. 22 is a histogram showing an example of variation in an etching removal in every region divided by the common mesh for the etching process according to the embodiment of the present invention;

FIG. 23 is a histogram showing an example of variation in reduction in film thickness in every region divided by the common mesh for the CMP process according to the embodiment of the present invention;

FIG. 24 is a histogram showing an example of variation in an etching removal in every region divided by the common mesh for the etching process according to the embodiment of the present invention;

FIG. 25 is a diagram showing an example of a comprehensive performance data according to the embodiment of the present invention;

FIG. 26 is a diagram showing an example of a distribution of variation in a residual SiO₂ film thickness according to the embodiment of the present invention;

FIG. 27 is a diagram showing another example of a common mesh according to the embodiment of the present invention;

FIG. 28 is a diagram showing another example of a common mesh data of the film deposition process according to the embodiment of the present invention;

FIG. 29 is a diagram showing another example of a the common mesh data of the CMP process according to the embodiment of the present invention;

FIG. 30 is a diagram showing another example of a the common mesh data of the etching process according to the embodiment of the present invention;

FIG. 31 is a diagram showing another example of a comprehensive performance data according to the embodiment of the present invention;

FIG. 32 is a diagram showing another example of variation in a residual SiO₂ film thickness according to the embodiment of the present invention;

FIG. 33 is a flowchart illustrating an example of a performance predicting method according to the embodiment of the present invention; and

FIG. 34 is a flowchart illustrating an example of a manufacturing method of a semiconductor device according to the embodiment of the present invention.

### DETAILED DESCRIPTION OF THE INVENTION

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

Various aspects of the present invention provide apparatus and method of predicting performance in a wafer of a semiconductor manufacturing process and a semiconductor device, which are capable of reducing a calculation amount and calculation time when predicting the performance in the wafer by an in-plane characteristics distribution simulation, and a manufacturing method of a semiconductor device.

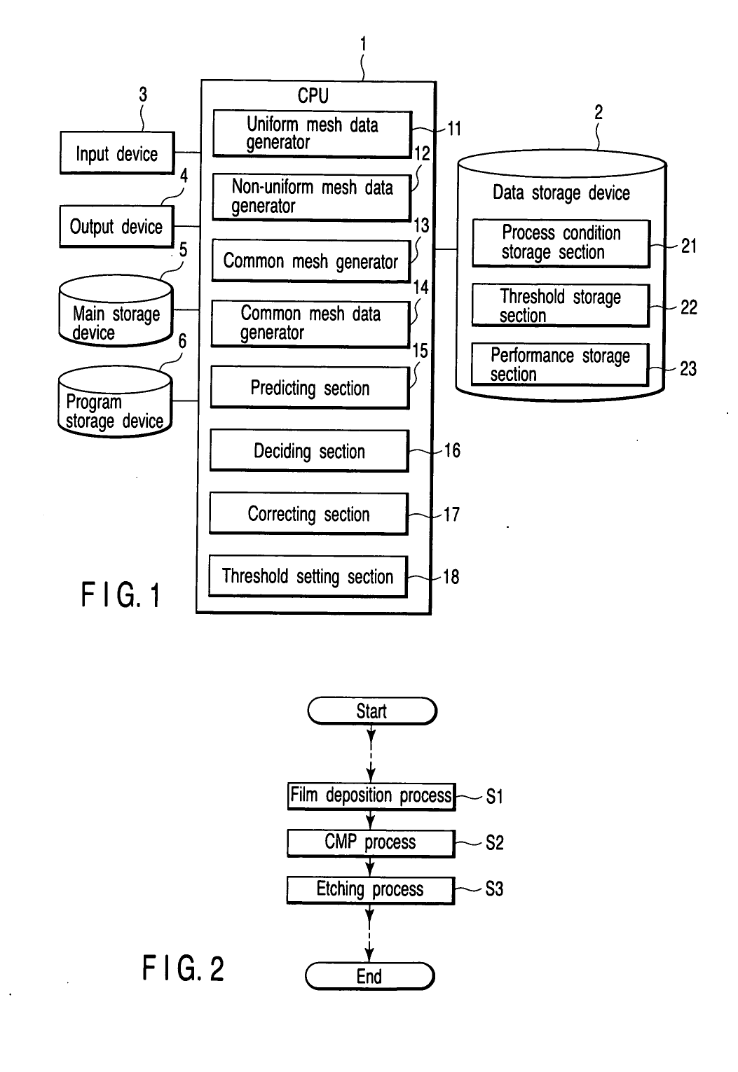

FIG. 1 shows an example of a performance prediction apparatus (a simulation apparatus) according to an embodiment of the present invention. As shown in FIG. 1, the performance prediction apparatus according to this embodiment comprises a central processing unit (CPU) 1, a data storage device 2, an input device 3, an output device 4, a main storage device 5, and a program storage device 6. The CPU 1 comprises a uniform mesh data generator 11, a non-uniform mesh generator 12, a common mesh generator 13, a common mesh data generator 14, a predicting section 15, a deciding section 16, a correcting section 17 and a threshold setting section 18.

A process condition storage section 21 in the data storage device 2 stores individual initial (current) process conditions of a series of process steps in manufacturing a semiconductor device. The process conditions include a target value of each process step, an in-plane characteristics distribution in each process step, a variation amount among lots and/or wafers in each process step, a variation amount among manufacturing equipments, a variation amount within a chip, and the like. The target value of each process step is input through, e.g., the input device 3. The variation amount in each process step or the in-plane characteristics distribution can be set to make reference to measured data or virtual data.

In this embodiment, a process of forming an isolation, e.g., a shallow trench isolation (STI) will be taken as an example and described in order to facilitate an explanation of a series of process steps in manufacturing a semiconductor device. Here, although a description will be given as to the isolation process, the present invention can be similarly applied to variety of other series of process steps. The isolation process includes, e.g., a silicon nitride film (an Si₃N₄ film) deposition process at step S1, a chemical mechanical polishing (CMP) process at step S2 and an etching process at step S3 as shown in FIG. 2.

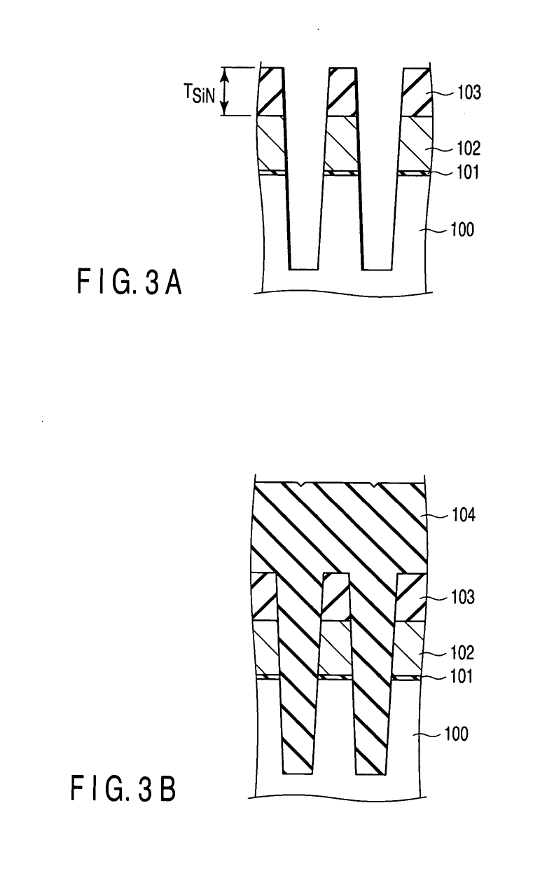

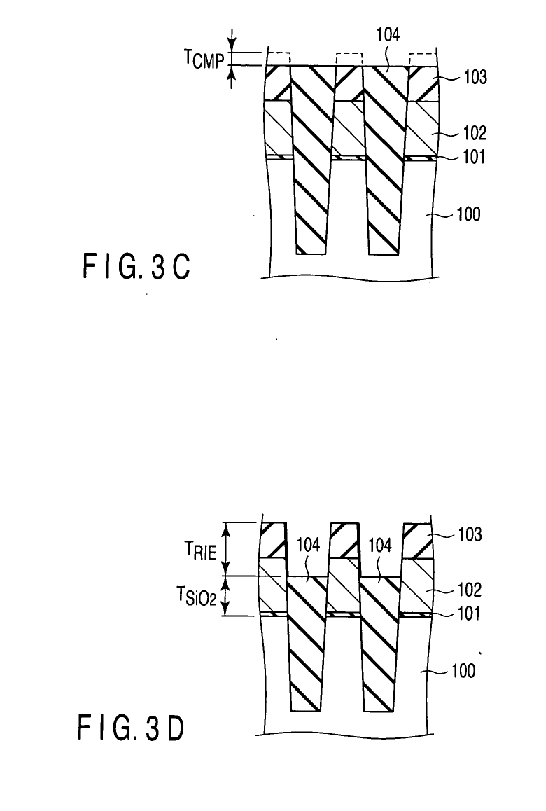

The isolation process is described briefly with referring to process sectional diagrams shown in FIGS. 3A to 3D.

At step Si, as shown in FIG. 3A, after a gate insulator 101 and a polysilicon layer 102 are formed on a semiconductor substrate, e.g., a silicon (Si) substrate 100, a silicon nitride film (Si₃N₄ film) 103 is deposited by chemical vapor deposition (CVD) or the like, and then an isolation trench is formed in the Si₃N₄ film 103, polysilicon layer 102 and Si substrate 100 by photolithography and etching. Here, a film thickness TSiN of the Si₃N₄ film 103 is determined as a performance of the procedure at step S1.

At step S2, as shown in FIG. 3B, a silicon oxide film (SiO₂ film) 104 is deposited by CVD or the like to fill the isolation trench. Then, the SiO₂ film 104 deposited on the surface is planarized by CMP using the Si₃N₄ film 103 as a stopper, as shown in FIG. 3C. A removal (a reduction in film thickness) of the Si₃N₄ film 103 T_{CMP} is determined as a performance of the procedure at step S2.

At step S3, as shown in FIG. 3D, the SiO₂ film 104 in the isolation trench is selectively removed to be lower than an upper surface of the polysilicon layer 102 by reactive ion etching (RIE) or the like. An etching removal T_{RIE} of the SiO₂ film 104 is determined as a performance of the procedure at step S3.

Furthermore, a residual film thickness of the SiO₂ film 104 T_{SiO2} above the surface of the Si substrate 100 is determined as a comprehensive performance which has been processed through the series of processes from steps S1 to S3. Although the processes from steps S1 to S3 are described in this embodiment for the convenience's sake, processing of the embodiment is also performed with respect to variety of the other series of process steps, of course.

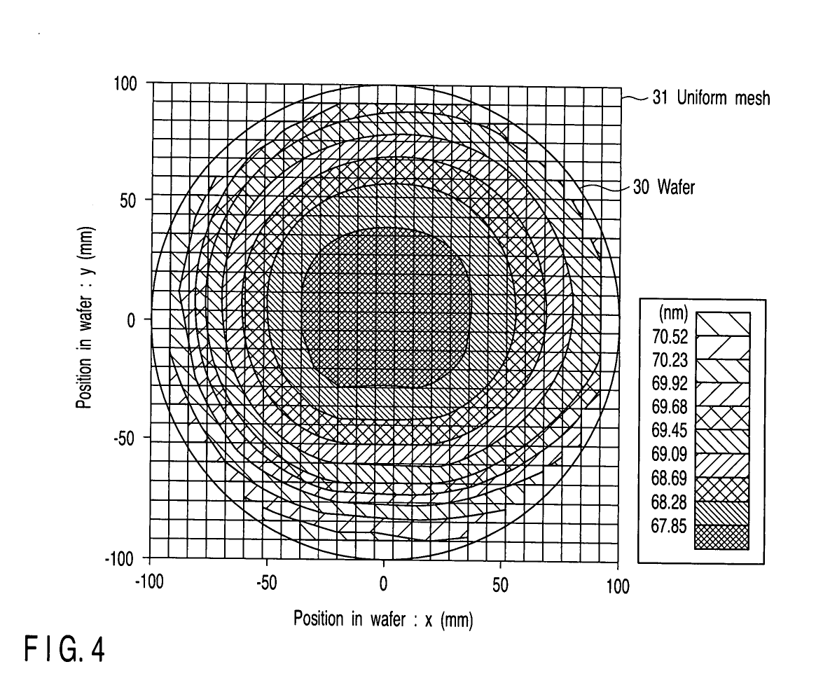

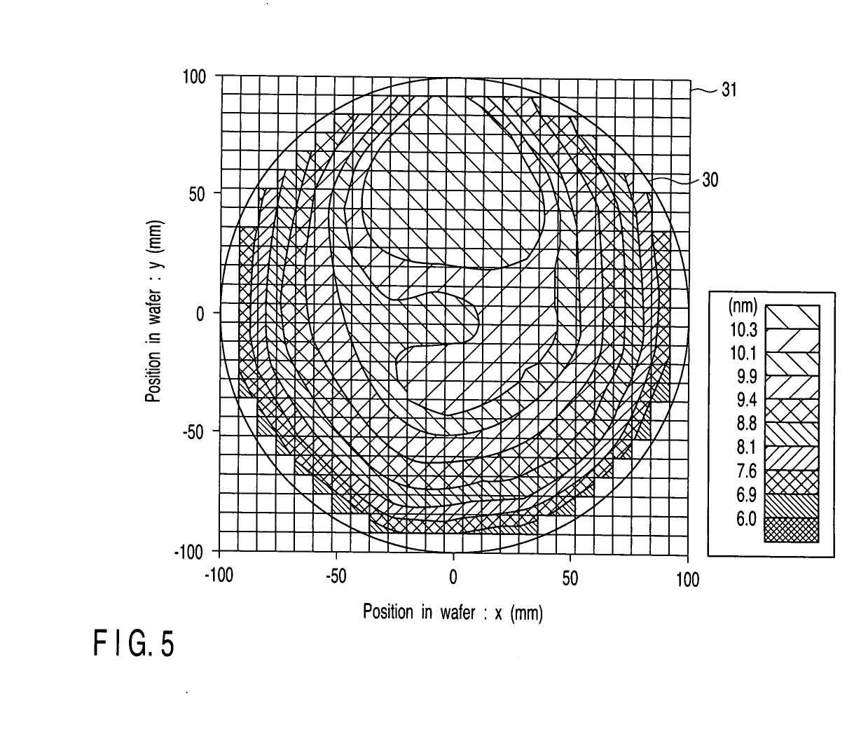

The uniform mesh data generator 11 shown in FIG. 1 reads the each initial (current) process conditions of each of processes from the process condition storage section 21. With respect to each of the series of processes from steps S1 to S3 depicted in FIG. 2, the uniform mesh data generator 11 divides a wafer 30 with a uniform mesh 31, and predicts a performance based on the read process conditions and generates in-plane characteristics distribution data of the performance (which will be referred to as “uniform mesh data” hereinafter), as shown in FIGS. 4 to 6. Incidentally, size of an element mesh in the uniform mesh 31 is determined as small as to represent the in-plane characteristics distribution in each process from steps S1 to S3.

Each uniform mesh data shown in FIGS. 4 to 6 is a map showing a performance of each process step, and a vertical axis and a horizontal axis in each drawing represent distances from the center of the wafer in x and y direction, respectively. Each drawing shows an example of a wafer having a diameter of 200 mm. For example, FIG. 4 is a diagram showing a film thickness of the Si₃N₄ film by using isopachous lines while dividing an entire wafer surface based on a classification illustrated on the right-hand side of the drawing. Hatching in the drawing corresponds to each classification. A film thickness distribution of the Si₃N₄ film in FIG. 4 demonstrates an in-plane characteristics distribution that the film thickness is thin in the center of the wafer and thick in the peripheral part of the wafer.

In order to determine a size of an element mesh in the uniform mesh, a description will now be given with reference to another example shown in FIG. 7. FIG. 7 shows an example of an in-plane distribution of an Si₃N₄ film formed on a wafer having a diameter of 300 mm by a plasma CVD method. The film thickness is measured along a diameter of the wafer, and then plotted as a dotted line in the figure. In this example, since the Si₃N₄ film thickness changes drastically in a peripheral region of the wafer, thus the film thickness is finely measured in the peripheral region of the wafer but it is roughly measured in other inner region. That is, in a region from the center of the wafer (0 mm) to a 140 mm position, the thickness is plotted at 10 mm intervals, and in a region from 140 mm to 150 mm from the center, the thickness is plotted at 1 mm intervals. Therefore, as a uniform mesh which sufficiently represents such an in-plane characteristics distribution, an entire wafer surface must be divided into element meshes with 1 mm square in size.

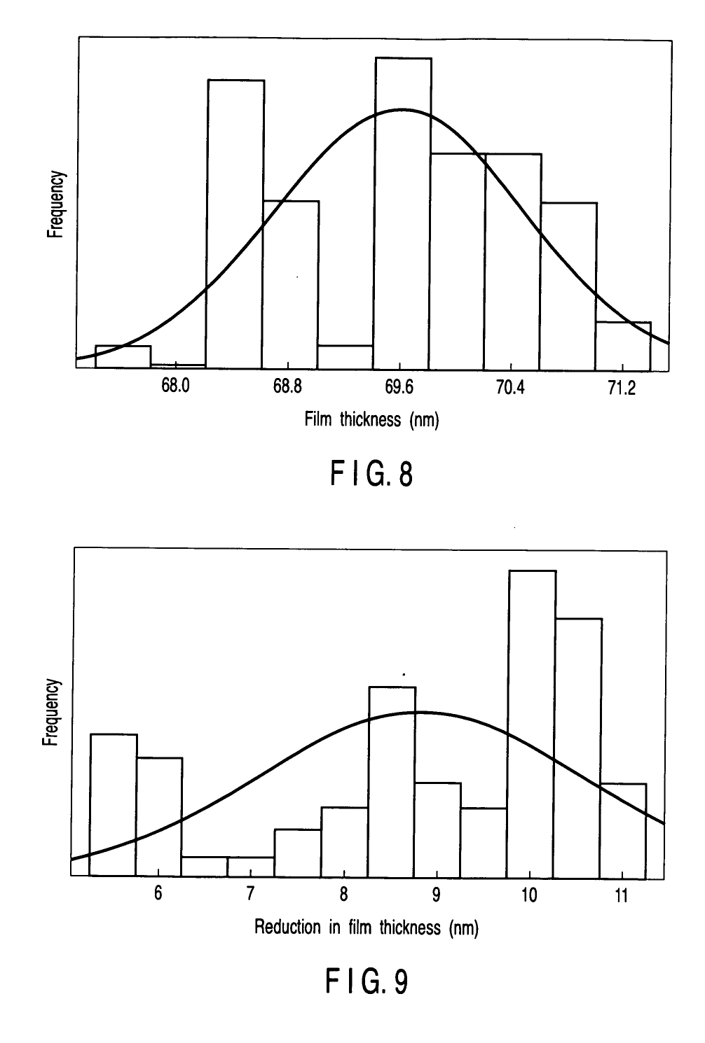

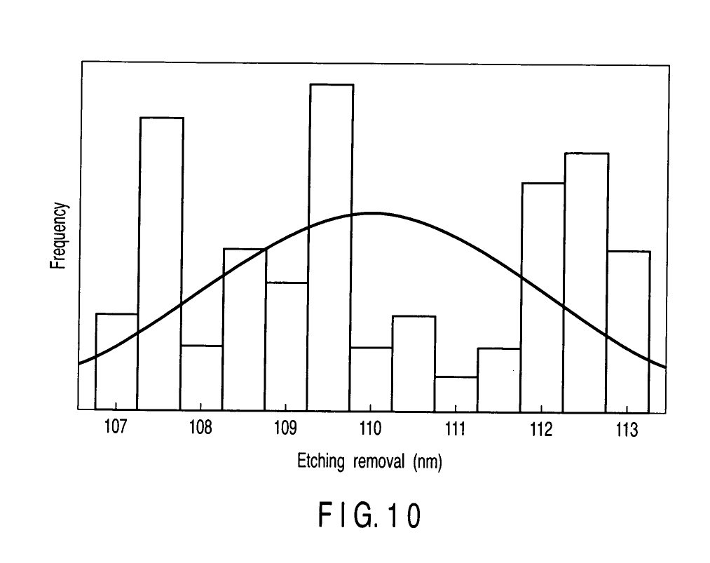

In FIGS. 4 to 6, an amount of local variation, such as an amount of variation among lots, an amount of variation among wafers, an amount of variation among devices or an amount of variation within a chip, are obtained with regard to each element mesh divided by the uniform mesh 31. In-plane characteristics distributions of the variation shown in FIGS. 4 to 6 can be represented in a form of a histogram. The respective variation can be represented as such variation in a film thickness T_{SiN} of the Si₃N₄ film 103 as shown in FIG. 8, variation in reduction in a film thickness T_{CMP} of the SiO₂ film 104 as shown in FIG. 9, and variation in an etching removal T_{RIE} of the SiO₂ film 104 by RIE as shown in FIG. 10, respectively. Further, equal average value of measured data in each uniform element mesh 31 is connected with each other in the entire wafer 30 to represent the in-plane characteristics distribution.

Furthermore, a through-simulation which predicts a performance after the series of processes from steps S1 to S3 shown in FIG. 2 can be performed with the uniform mesh data depicted in FIGS. 4 to 6 being used as input data. In this case, however, since a calculation is executed to every element mesh divided by the uniform mesh 31, an enormous calculation time and calculation amount are required. For example, as described above for the wafer having a diameter of 300 mm with reference to FIG. 7, when the wafer surface is divided by using a uniform mesh having a size of 1 mm square, the number of total meshes in an effective region in the wafer is 70665.

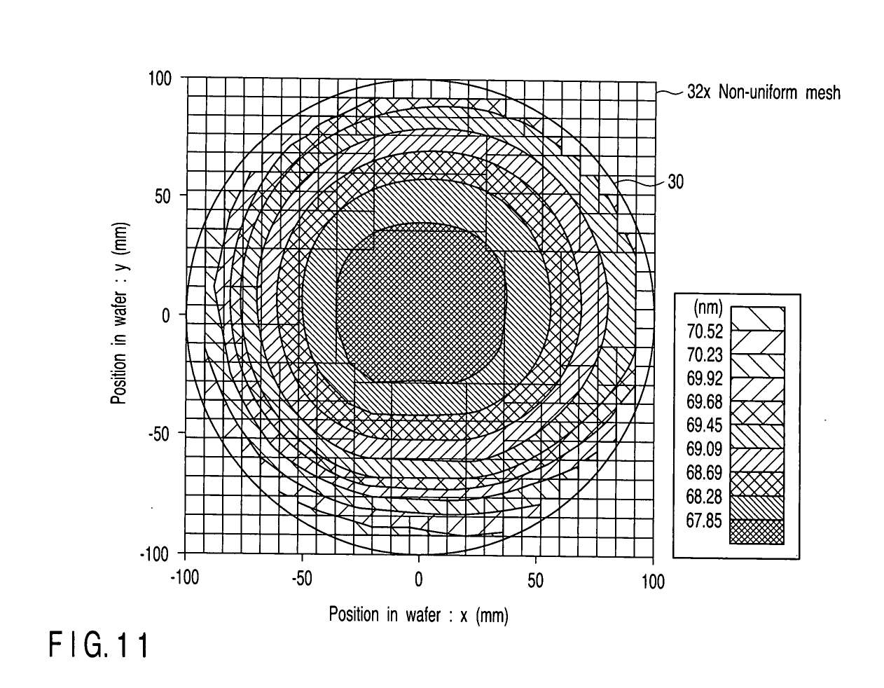

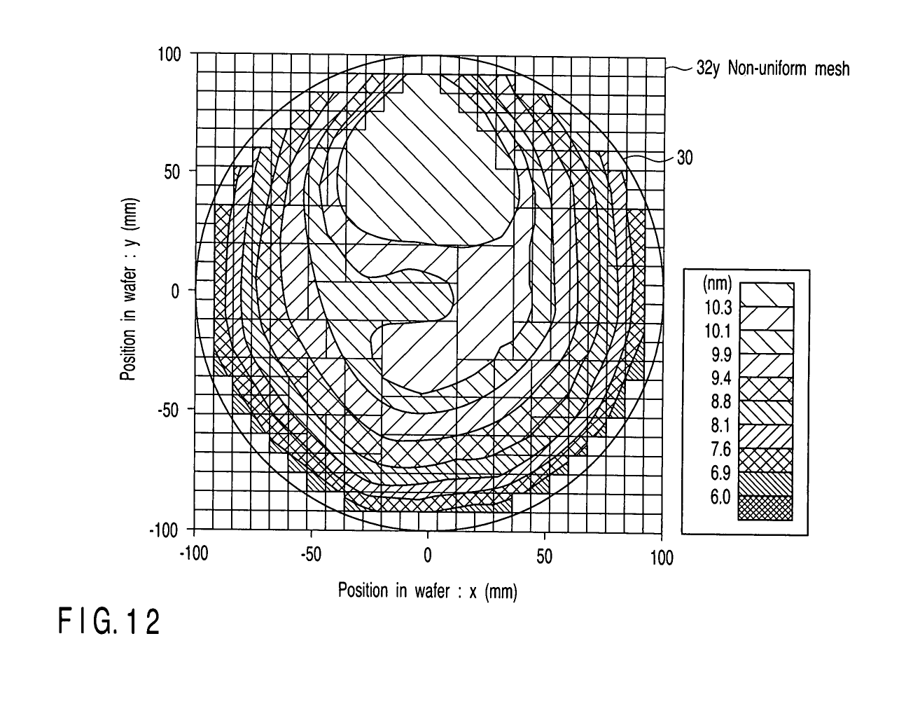

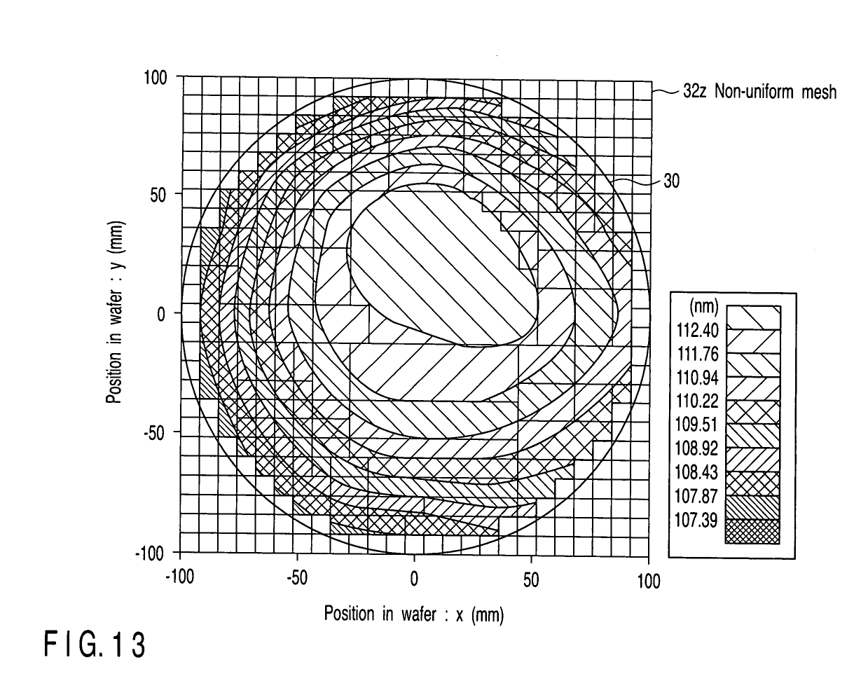

To reduce the calculation amount in the in-plane characteristics distribution simulation, a non-uniform mesh is generated first. The non-uniform mesh generator 12 shown in FIG. 1 generates optimized non-uniform meshes 32x, 32y and 32z, as shown in FIGS. 11 to 13, which non-uniformly divide the wafer surface 30 based on the uniform mesh data illustrated in FIGS. 4 to 6 with respect to each of the series of processes from steps S1 to S3 depicted in FIG. 2. In the step, for example, the non-uniform mesh generator 12 also reads threshold values (a criterion for combining) for a data variation among adjacent meshes from the threshold storage section 22 in the data storage device 2. Then, the non-uniform mesh generator 12 decides whether the variations in the in-plane characteristics distribution in the wafer 30 shown in FIGS. 4 to 6 are moderate or drastic by using the read threshold value. In a region around the central part of the wafer 30 where the variation in the in-plane characteristics distribution is moderate, the element meshes in the uniform mesh 31 are combined to make a larger division. On the other hand, in a region near edge of the wafer 30 where the variation in the in-plane characteristics distribution is drastic, the uniform mesh 31 may be held or further divided smaller.

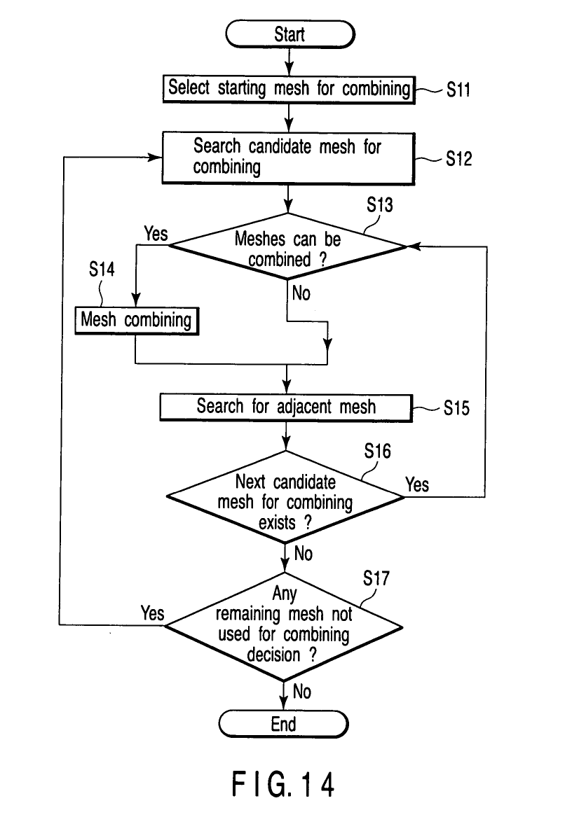

As another example, a method using a statistical technique to automatically generate a non-uniform mesh will now be described. FIG. 14 is a process flowchart showing the method of automatically generating the non-uniform mesh.

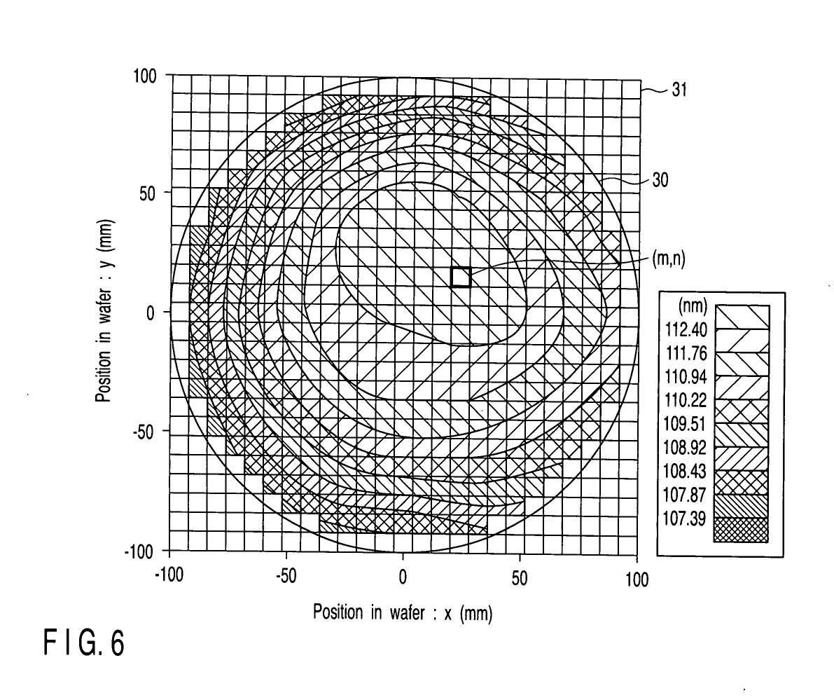

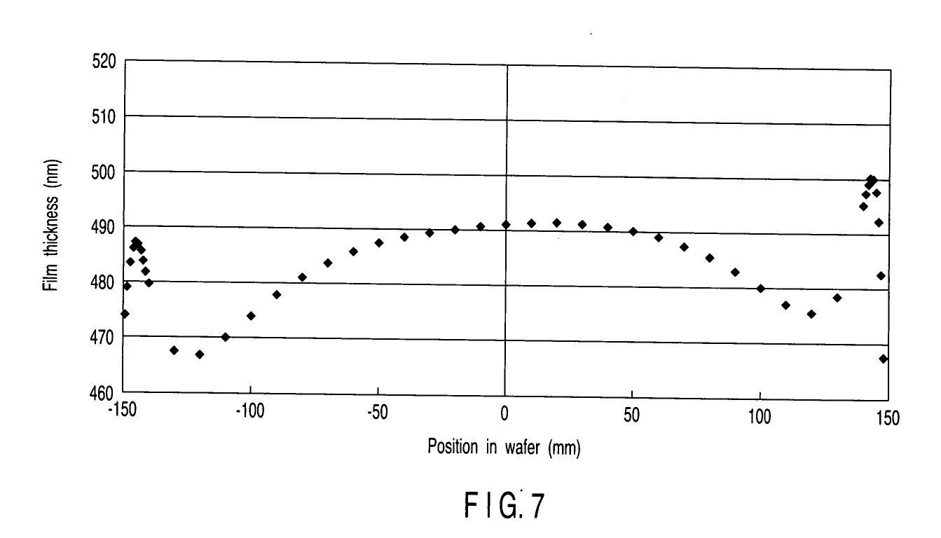

Here, a mesh position in a wafer is expressed as (x, y) and data included in one element mesh (x, y) is assumed to be represented by a distribution function f(x, y). First, at a starting mesh for combining selection step shown as step S11, an element mesh in which a gradient of the in-plane characteristics distribution of data to adjacent element meshes is most moderate within the wafer is selected. For example, an average value of data in each element mesh is compared with that of each adjacent element mesh, and an element mesh having the minimum difference in the average value is selected as a starting mesh for combining. Here, it is assumed that an element mesh (m, n) is selected as the starting mesh, as indicated in a thick line in FIG. 6. The starting mesh for combining is an element mesh (m, n) located in a region where an in-plane characteristics distribution is most uniform in the wafer.

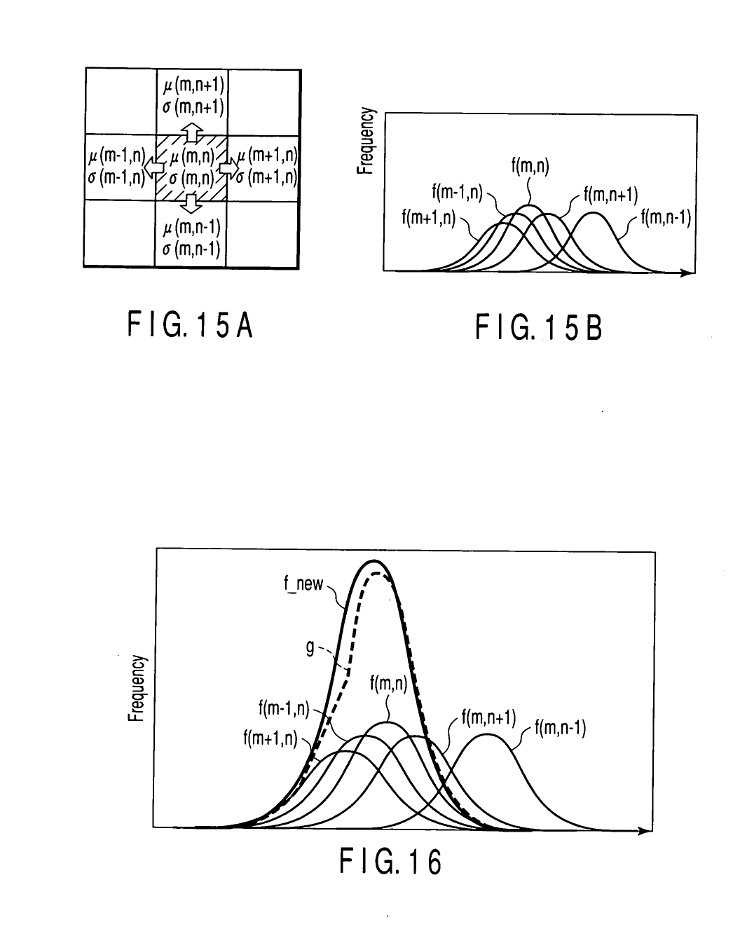

Then, at a candidate mesh for combining search step S12, as shown in FIG. 15A, four element meshes (a mesh (m−1, n), a mesh (m, n−1), a mesh (m+1, n), a mesh (m, n+1)) adjacent to the starting mesh (m, n) are compared in an average value μ(x, y) and a variance σ(x, y) of the data to those in the starting mesh (m, n) and the threshold value. Further, a mesh having the minimum difference in the average value μ(x, y) of the data from that of the starting mesh (m, n) is detected and selected as a candidate mesh for combining. FIG. 15B shows an example of a distribution function f(x, y) of each element mesh. In this example, the mesh (m−1, n) having the minimum difference in the average value from that of the starting mesh (m, n) is selected as the candidate mesh for combining.

At a combining availability decision step S13, a decision is made upon whether a sum of data in the starting mesh (m, n) and the candidate mesh (m−1, n) can be expressed by the same distribution function f as that of the starting mesh. For example, as shown in FIG. 16, a new data containing both data expressed as f(m, n) and f(m−1, n) as component elements is generated. The generated data is denoted as g. Furthermore, if f is a normal distribution function, then g is subjected to normal distribution approximation to produce f₁₃ new. A homoscedastic test and/or a significance test of an average value is performed with respect to the data g and the data f₁₃ new, and a value p is used to test whether g and f₁₃ new are statistically matched with each other. The value p is an index used to decide on presence/absence of a statistical significant difference with respect to two or more distribution functions. More particularly, the value p is an index which is used to decide whether a null hypothesis is to be rejected in a hypothesis test, and a reference value in the decision is generally 0.05. If the value p with which a given test statistic has been calculated is larger than the reference value, the null hypothesis is rejected. That is, it is determined that “it cannot be said that this statistic is not equal”. This value p for the test is used to decide whether the meshes can be combined. If the value p is smaller than the reference value, e.g., 0.05, it cannot be said that g and f₁₃ new express the same distribution, namely, it means that a difference in data distribution between the starting mesh (m, n) and the candidate mesh (m−1, n) is large, which is inappropriate for combining the meshes. On the contrary, if the value p is larger than the reference value, it is determined that g and fnew have statistically the same distribution, and hence the starting mesh (m, n) and the candidate mesh (m−1, n) can be combined with each other. The severity of the mesh combining availability decision can be controlled by a variety of methods. The reference value to the value p is changed to provide a different threshold in the mesh combining decision, for example.

If it is decided that the meshes can be combined at step S13, the mesh (m, n) and the mesh (m−1, n) are combined with each other at step S14, the f₁₃ new is stored as new data, then the process advances to step S15. If it is decided that the meshes cannot be combined with each other at step S13, the process directly advances to step S15.

At step S15, the same searching operation for the next candidate mesh for combining is performed with respect to the other adjoining meshes, and it is decided whether the next candidate mesh for combining exists, at step S16. If there is a next candidate mesh for combining, the process returns to step S13 to repeat the combining availability decision. If there is no candidate mesh remained with the starting mesh (m, n) as a starting point, the process advances to step S17.

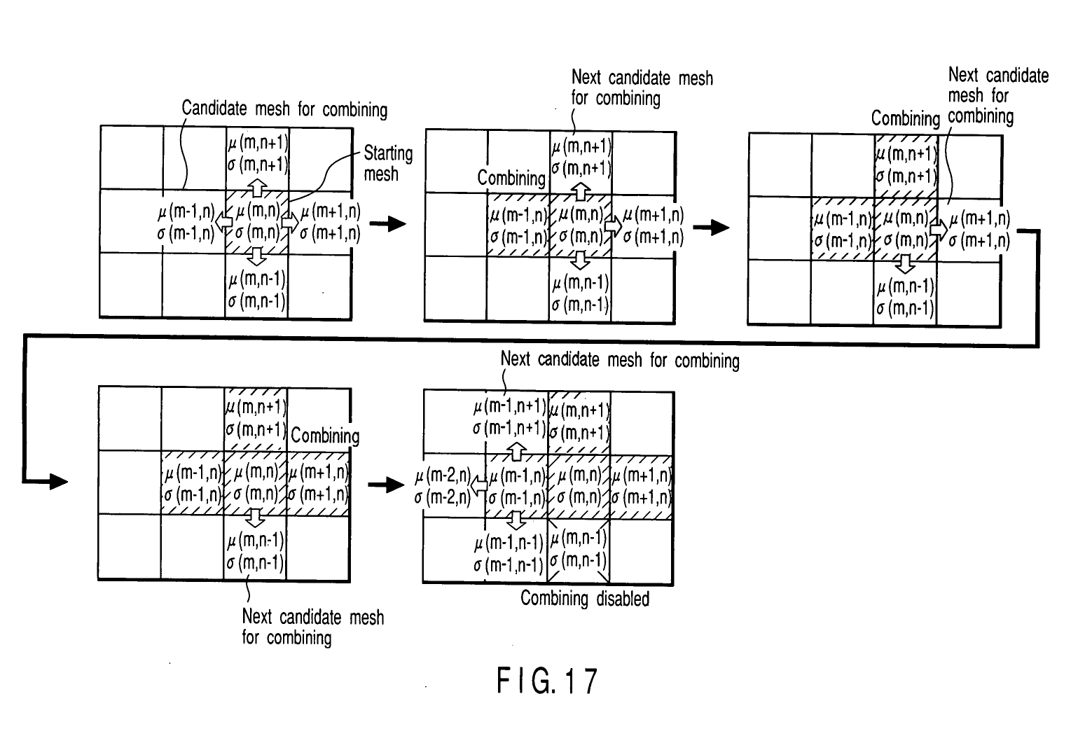

Summarizing the combining procedure of meshes to generate a non-uniform mesh with regard to the starting mesh (m, n) for combining as described above, the procedure is as shown in FIG. 17. The mesh (m−1, n) having the minimum difference in the average data value is first selected as the candidate mesh for combining from four meshes adjacent to the starting mesh (m, n). If it is statistically determined that the mesh (m−1, n) can be combined and the meshes are combined with each other. Then the mesh (m, n+1) having the second minimum difference in the average value is selected as the next candidate mesh for combining. Likewise, if it is determined that the mesh (m, n+1) can be combined, the corresponding meshes are combined with each other. Then the mesh (m−1, n) is selected as the next candidate mesh for combining. Likewise, it is determined that the mesh (m−1, n) can be combined and then the corresponding meshes are combined with each other. At last, the mesh (m, n−1) having the largest difference in the average value is selected as the next candidate mesh for combining. In this case, however, since the value p of the integrated distribution function becomes smaller than the reference value, it is statistically determined that combining is not allowed.

Again referring to FIG. 14, at step S17, a deciding is made upon whether there is a remaining mesh which is not used in the combining availability decision. If there is an unused mesh, the process returns to step S11 to start detection of the next starting mesh for combining. If there is no unused mesh at step S17, generation of the non-uniform mesh is completed.

According to this method, a decision of combining a plurality of element meshes is performed by testing whether distribution functions of data included in respective meshes before and after the combining are statistically equal to each other, thereby enabling automatic generation of the non-uniform mesh.

With the method described above, the non-uniform mesh in the wafer can be automatically generated from the uniform mesh.

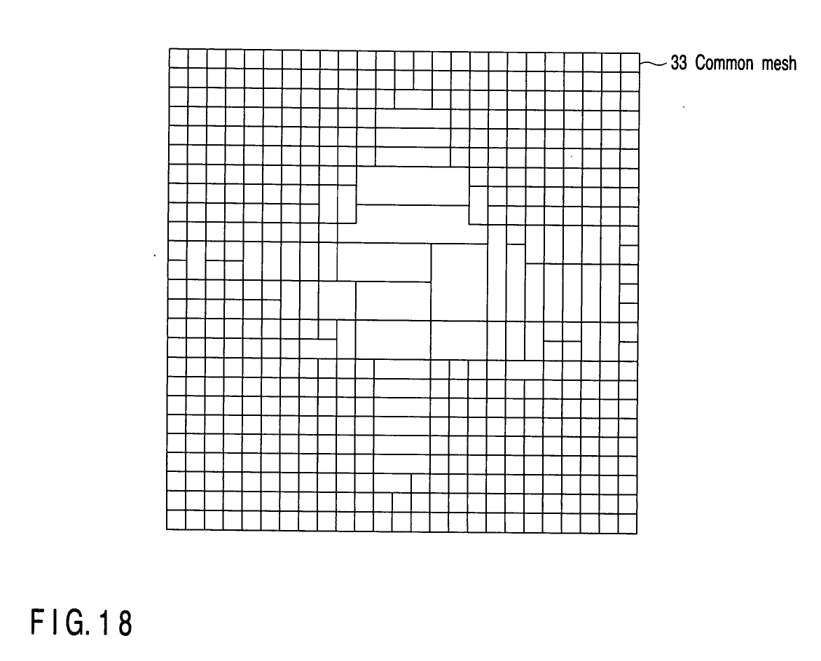

The common mesh generator 13 shown in FIG. 1 generates a “common mesh” 33 as illustrated in FIG. 18 by selecting the smallest non-uniform mesh for every region in the wafer 30 from the plurality of non-uniform meshes 32x, 32y and 32z as shown in FIGS. 11 to 13. In other words, the plurality of non-uniform meshes 32x, 32y and 32z are superimposed, and a smallest mesh is selected out of them with respect to every region in the wafer 30 to generate the common mesh 33. An operation to generate this common mesh will be referred to as “superimposition” hereinafter.

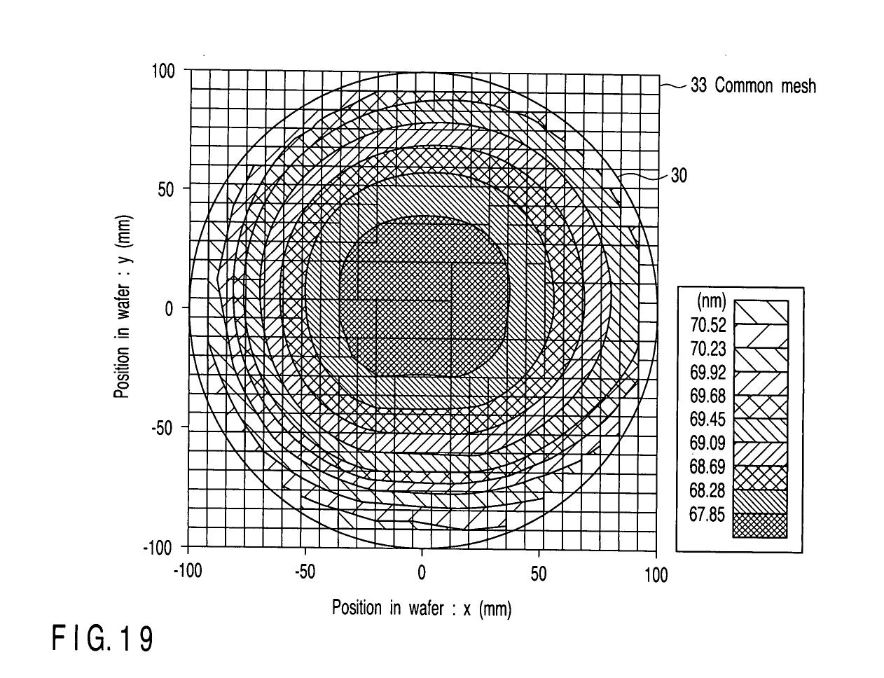

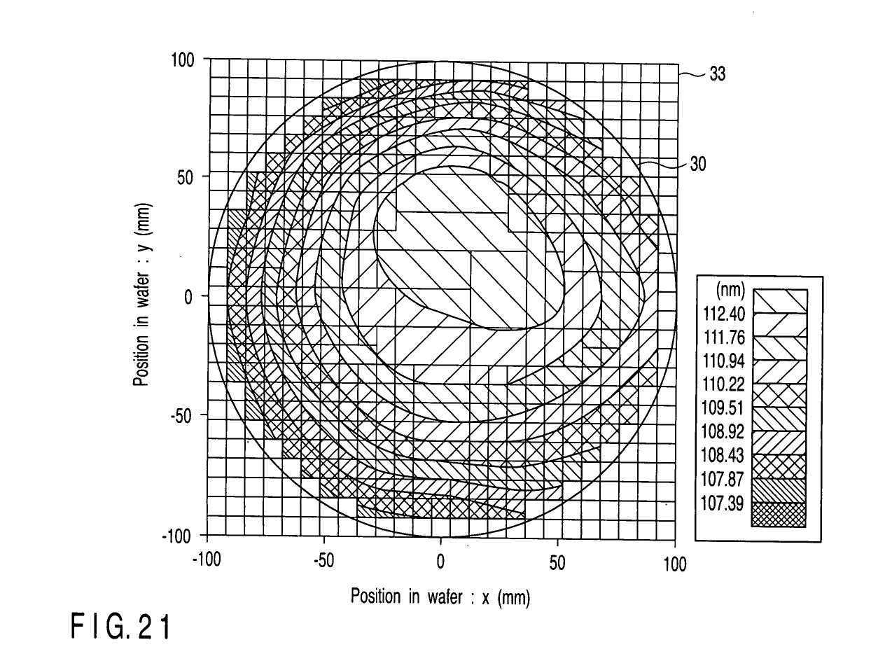

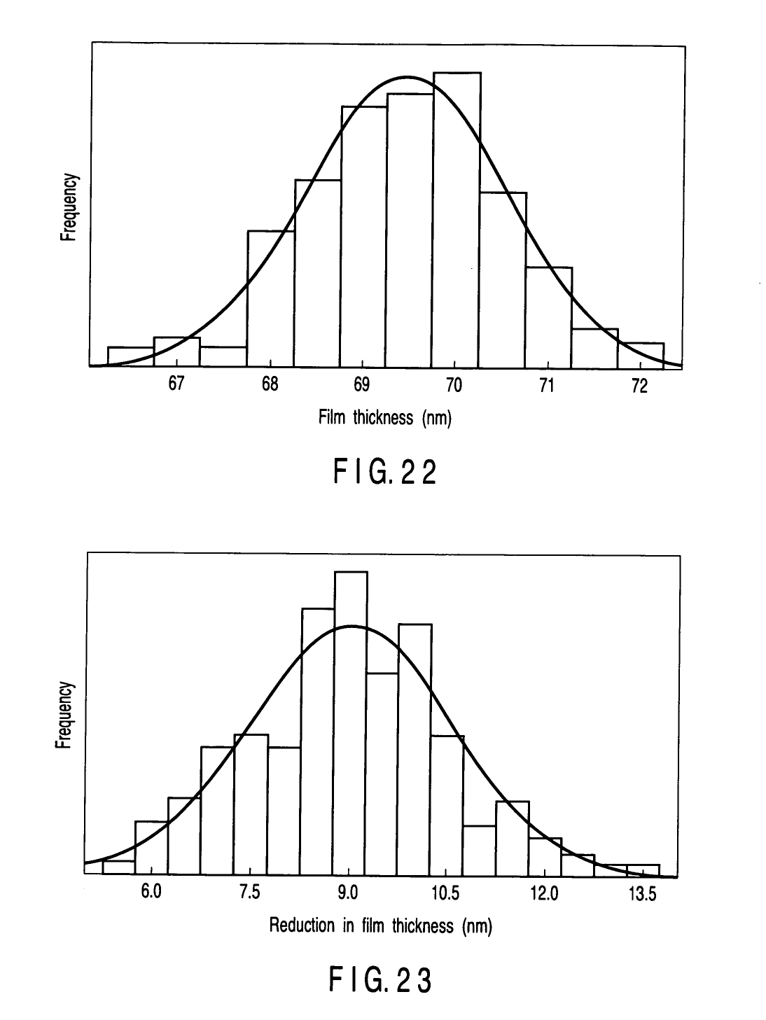

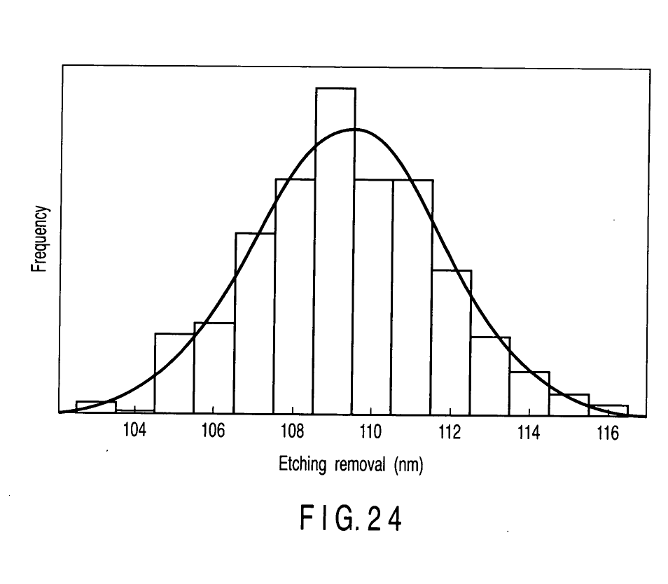

As shown in FIGS. 19 to 21, the common mesh data generator 14 depicted in FIG. 1 represents performances of the respective processes from steps S1 to S3 illustrated in FIG. 2 by using the common mesh 33 shown in FIG. 18 to generate each “common mesh data”. In each region divided by the common mesh 33 of the common mesh data illustrated in FIGS. 19 to 21, variations of the film thickness T_{SiN} of the Si₃N₄ film 103, the reduction in film thickness T_{CMP} of the SiO₂ film 104 by CMP and the etching removal T_{RIE} of the SiO₂ film 104 are shown as histograms as shown in FIGS. 22 to 24, respectively. Equal average values of such data in each mesh as shown in FIGS. 22 to 24 are connected with each other, thereby representing an in-plane characteristics distribution in the wafer as respectively depicted in FIGS. 19 to 21.

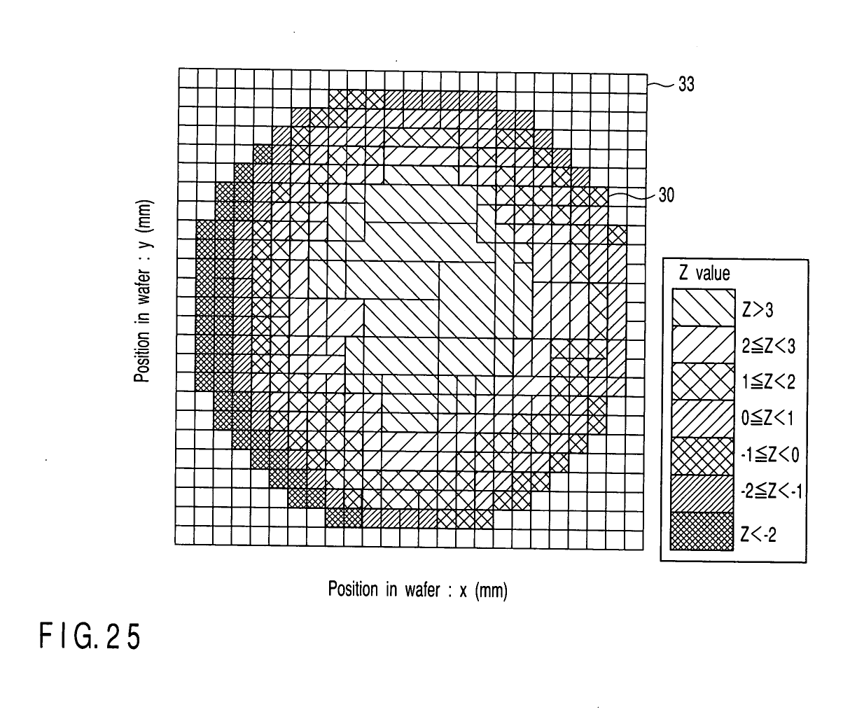

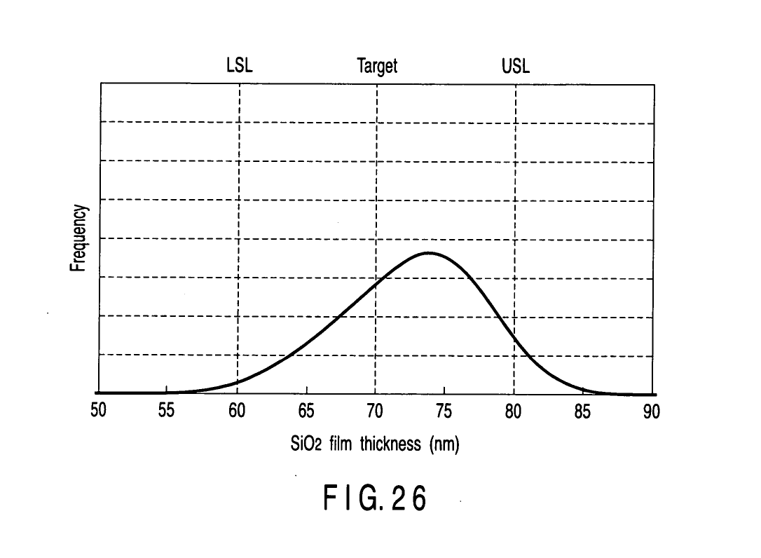

The predicting section 15 shown in FIG. 1 performs a through simulation using the common mesh data depicted in FIGS. 19 to 21 as input data, and predicts a comprehensive performance of a final product which has been processed through the series of process steps from steps S1 to S3 shown in FIG. 2 with regard to every region divided by the common mesh 33 as depicted in FIG. 25. FIG. 25 shows an example of an in-plane characteristics distribution or an in-plane distribution of a z-value, which is an index indicating a process capability. A region having a lower defect probability is shown with a larger z-value and, for example, a region has a defect probability which is not greater than 0.27% when the z-value is larger than 3. Here, the z-value is evaluated with respect to a residual film thickness T_{SiO2} of the SiO₂ film 104 after step S3 of FIG. 2. For example, in regard to specification values of the residual film thickness T_{SiO2} of the SiO₂ film 104, an upper specification limit (USL) is set as 80 nm with respect to a target value 70 nm, and a lower specification limit (LSL) is set as 60 nm. A proportion of a region divided by the common mesh 33 being out of the specification is reflected in the z-value shown in FIG. 25. Data of the comprehensive performance of the final product shown in FIG. 25 is stored in the performance storage section 23 of the data storage device 2.

The deciding section 16 shown in FIG. 1 decides whether the entire region in the wafer 30 satisfies the specification value based on the comprehensive performance of the final product depicted in FIG. 25. For example, if all performances represented in the common mesh 33 in the wafer 30 shown in FIG. 25 are combined with each other and the z-value of the entire wafer becomes not smaller than 3, it is decided that the entire region in the wafer 30 has satisfied the specification value.

The correcting section 17 shown in FIG. 1 performs sensitivity analysis by changing the initial process conditions based on the comprehensive performance depicted in FIG. 25, extracts parameters of the process conditions having a higher influence to improve the performance, and optimizes each of the parameters to be Z value large. Additionally, the correcting section 17 corrects the parameters of the process conditions based on the optimized parameters and updates the process conditions stored in the process condition storage section 21.

The threshold setting section 18 shown in FIG. 1 feeds back a threshold value stored in the threshold storage section 22 based on the comprehensive performance of the final product depicted in FIG. 25 to optimize mesh division of the non-uniform meshes 32x, 32y and 32z illustrated in FIGS. 11 to 13. That is, a threshold value stored in the threshold storage section 22 shown in FIG. 1 is reset/updated as follows. In FIG. 25, in a region in the wafer 30 where the large z-value is provided and defects are rarely generated, the threshold is set to be rather moderate since the prediction accuracy can be relaxed, on the other hand, in a critical region in the wafer 30, a threshold value is set to be rather rigorous since a higher prediction accuracy is required.

The uniform mesh generator 11 shown in FIG. 1 predict a new performance according to the corrected process conditions determined by the correcting section 17 for each of the series of process steps depicted in FIG. 2 and generates a new uniform mesh data (not shown) representing a new in-plane characteristics distribution with regard to each process step.

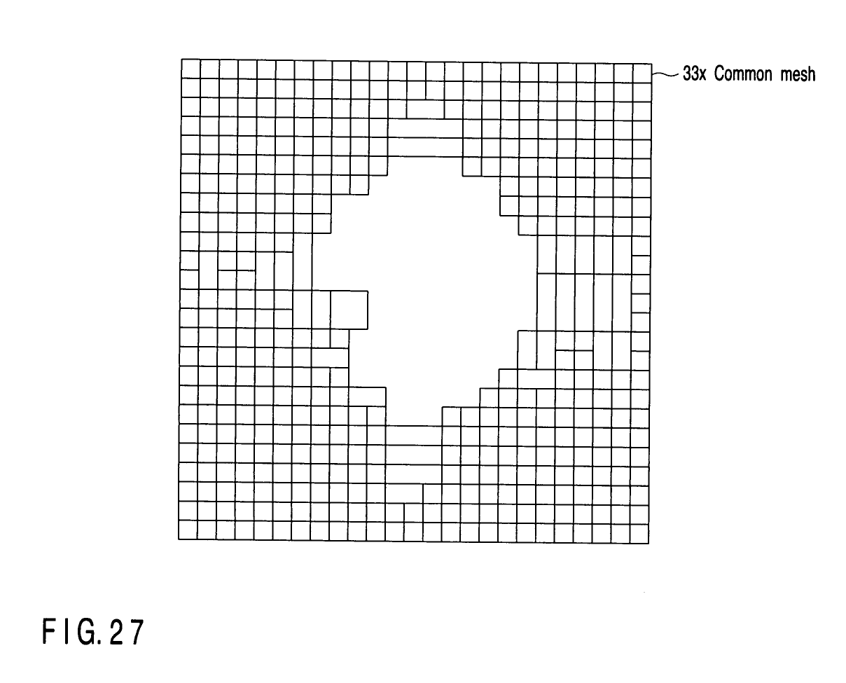

The non-uniform mesh generator 12 shown in FIG. 1 further generates a new non-uniform mesh (not shown) corresponding to the new uniform mesh data by using a new threshold value if the threshold value is updated by the threshold setting section 18. In this case, in the new non-uniform mesh, a region having a larger margin in the non-uniform meshes 32x, 32y and 32z depicted in FIGS. 11 to 13 is further combined to be larger and a critical region in the same is further divided smaller. The common mesh generator 13 similarly performs superimposition with respect to the new non-uniform mesh to generate a new common mesh 33x as depicted in FIG. 27.

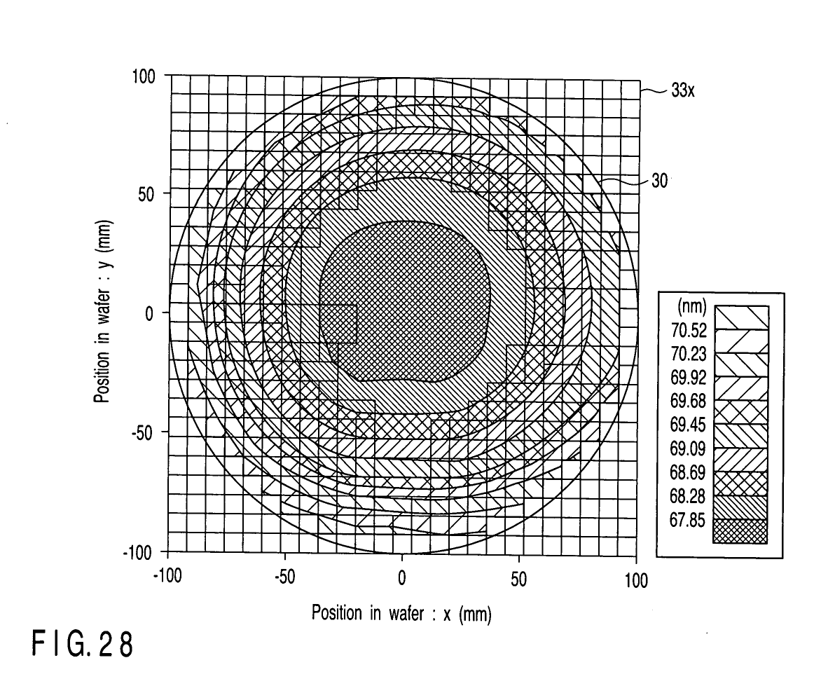

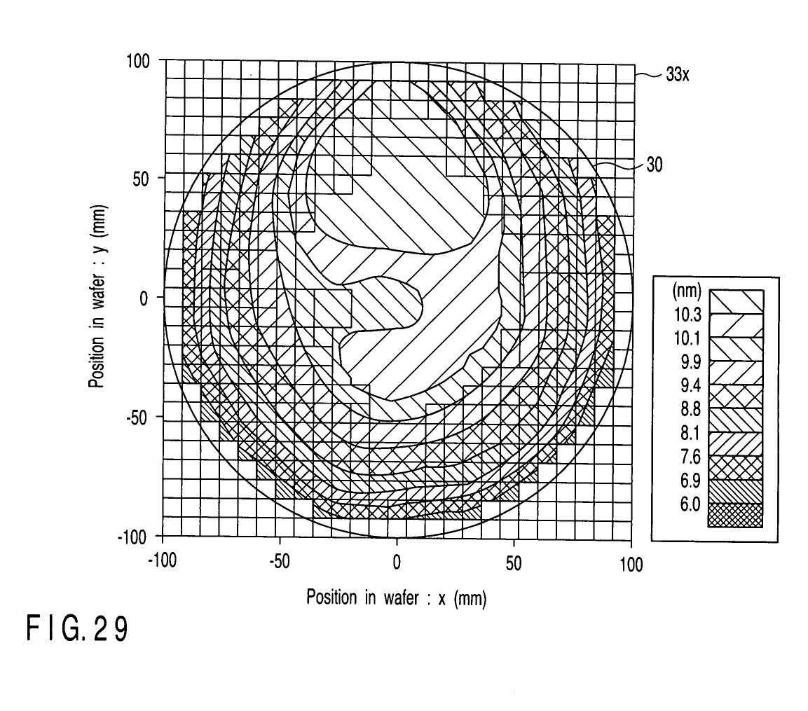

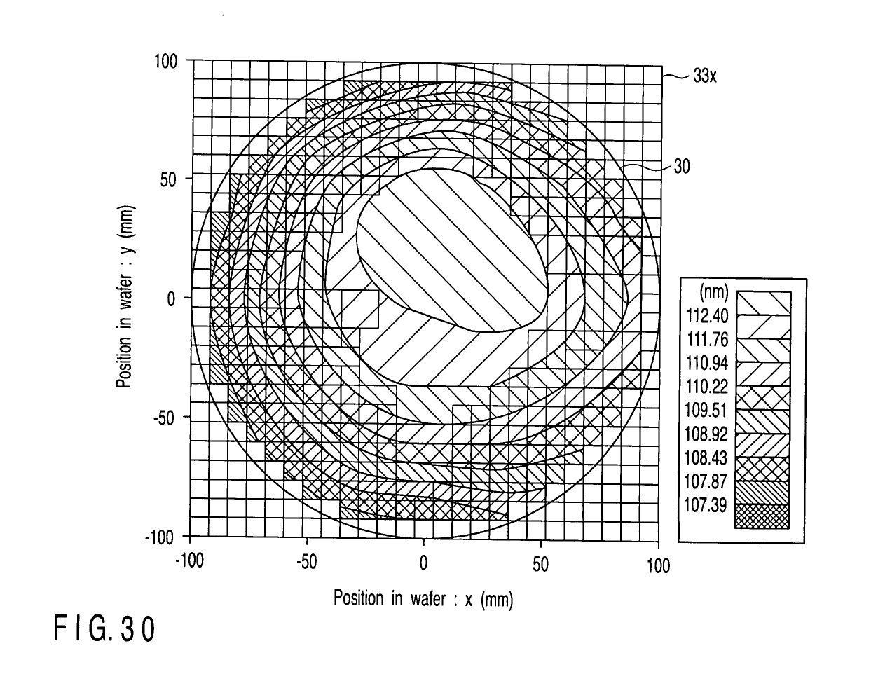

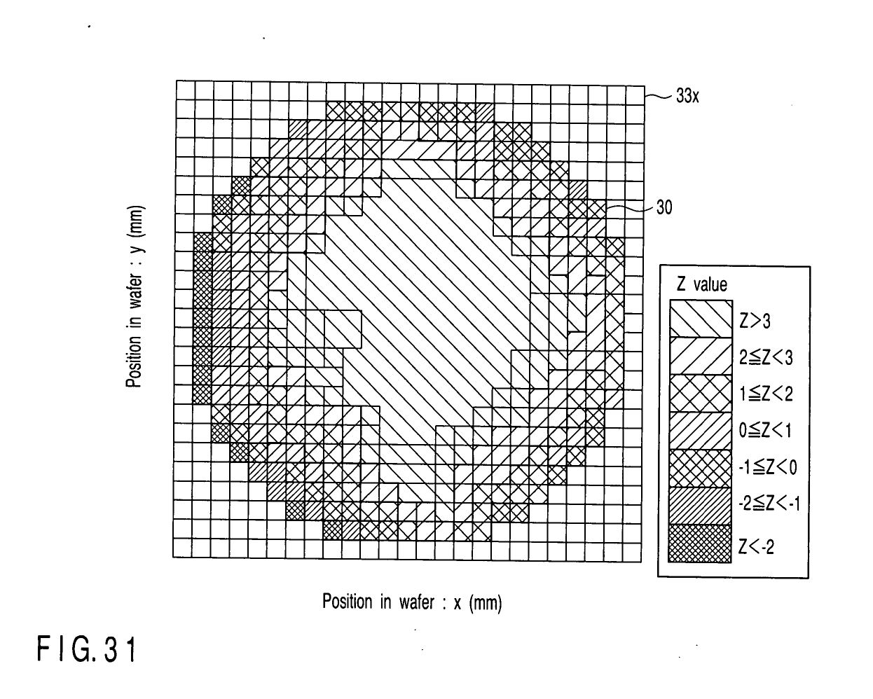

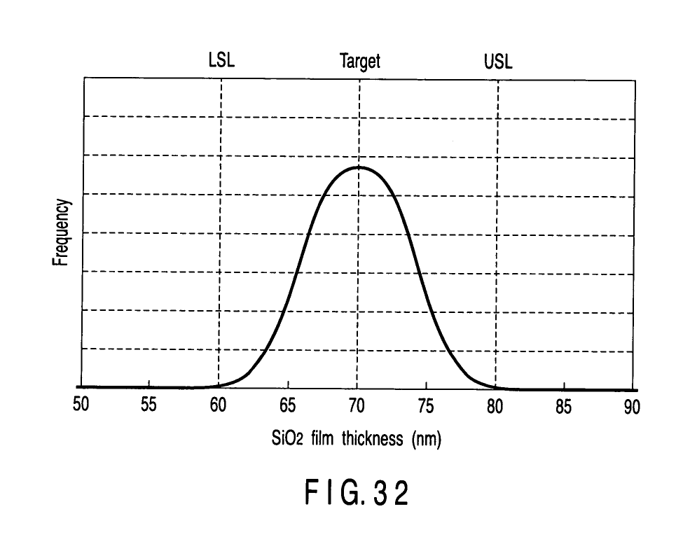

The common mesh data generator 14 shown in FIG. 1 applies the common mesh 33x depicted in FIG. 27 to the new in-plane characteristic distribution data and generate new common mesh data as shown in FIGS. 28 to 30. The predicting section 15 shown in FIG. 1 uses the new common mesh data depicted in FIGS. 28 to 30 as input data to perform another through simulation, and predicts a new comprehensive performance as illustrated in FIG. 31. FIG. 32 shows a distribution of a residual SiO₂ film thickness, i.e., variation of the SiO₂ film after step S3 shown in FIG. 2, according to the corrected process conditions.

The CPU 1 shown in FIG. 1 further comprises an input/output control device (an interface) and storage device managing means, which are not illustrated. The input/output control device (the interface) controls input/output of signals or the like between the CPU 1 and the input device 3 and/or the output device 4. The storage device managing means manages input/output between the data storage device 2 and the main storage device 5 and/or the program storage device 6.

The data storage device 2 comprises the process condition storage section 21 which stores initial process conditions and process conditions corrected by the correcting section 17, the threshold storage section 22 which stores a threshold value serving as a reference for combining of uniform element meshes to form the non-uniform meshes 32x, 32y and 32z, and the performance storage section 23 which stores a performance predicted by the predicting section 15.

As the input device 3, it can be used, e.g., a recognition device such as a keyboard, a mouse or an OCR, a graphic input device such as an image scanner, and/or a special input device such as a voice input device. As the output device 4, it can be used, e.g., a display device such as a liquid crystal display or a CRT display, and/or a printing device such as an ink-jet printer or a laser printer. The output device 4 can display on a monitor, e.g., a performance of the final product shown in FIG. 25 predicted by the predicting section 15 or the like.

The main storage device 5 serves as a temporary data memory which is utilized as a storage region or a working region in which data or the like used during program execution processing in the CPU 1 is temporarily stored. As the main storage device 5, it can be used, e.g., a semiconductor memory, a magnetic disk, an optical disk, a magneto optical disk, a magnetic tape or the like.

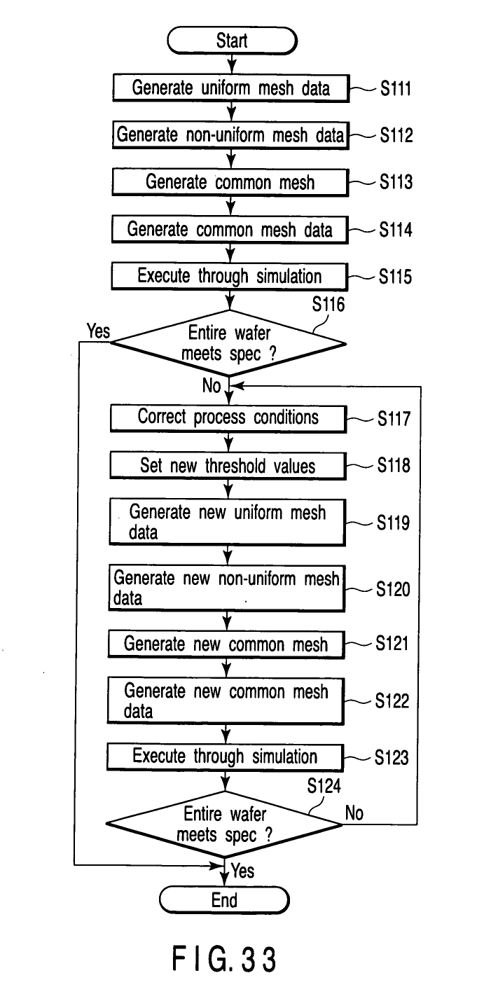

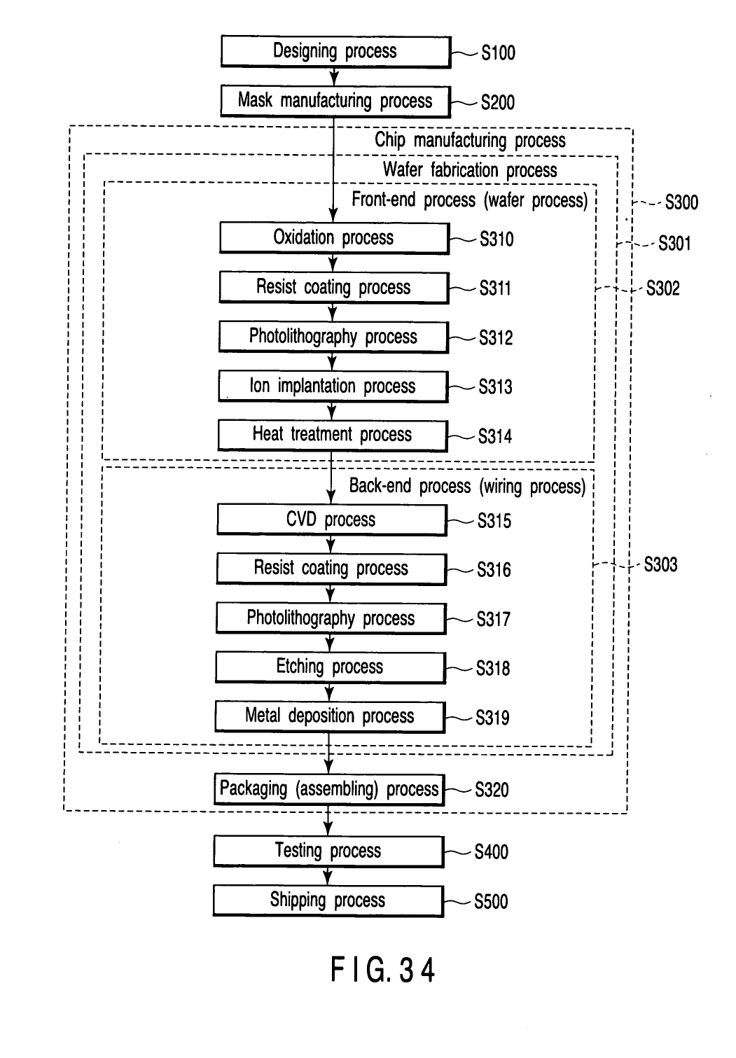

A process condition correcting method including a performance predicting method (a simulation method) based on an in-plane characteristics distribution simulation according to the embodiment of the present invention will now be described with reference to a flow chart of FIG. 33. The following process can also be included as a part of designing process S100 shown in FIG. 34.

(a) At step S111, the uniform mesh data generator 11 shown in FIG. 1 simulates performances of the series of process steps based on process conditions stored in the process condition storage section 24 and divides the wafer surface 30 by using a uniform mesh 31 to generate in-plane characteristics distribution data of a performance of each of the series of process steps from steps S1 to S3 depicted in FIG. 2 as uniform mesh data as shown in FIGS. 4 to 6.

(b) At step S112, the non-uniform mesh generator 12 shown in FIG. 1 reads threshold values stored in the threshold storage section 22 to decide whether variations in the in-plane characteristics distributions of the uniform mesh data depicted in FIGS. 4 to 6 are moderate or drastic. The element meshes of the uniform mesh 31 are combined with each other in a region where the variation in the in-plane characteristics distribution is moderate. On the other hand, the uniform meshes 31 are maintained in a region where the variation in the in-plane characteristics distribution is drastic. Consequently, as shown in FIGS. 11 to 13, optimized non-uniform meshes 32x, 32y and 32z which non-uniformly divide the wafer surface 30 are generated with respect to each of the processes from steps S1 to S3.

(c) At step S113, the common mesh generator 13 shown in FIG. 1 superimposes the plurality of non-uniform meshes 32x, 32y and 32z depicted in FIGS. 11 to 13, and selects the smallest mesh from these meshes in every region in the wafer 30 to generate a common mesh 33, as depicted in FIG. 18.

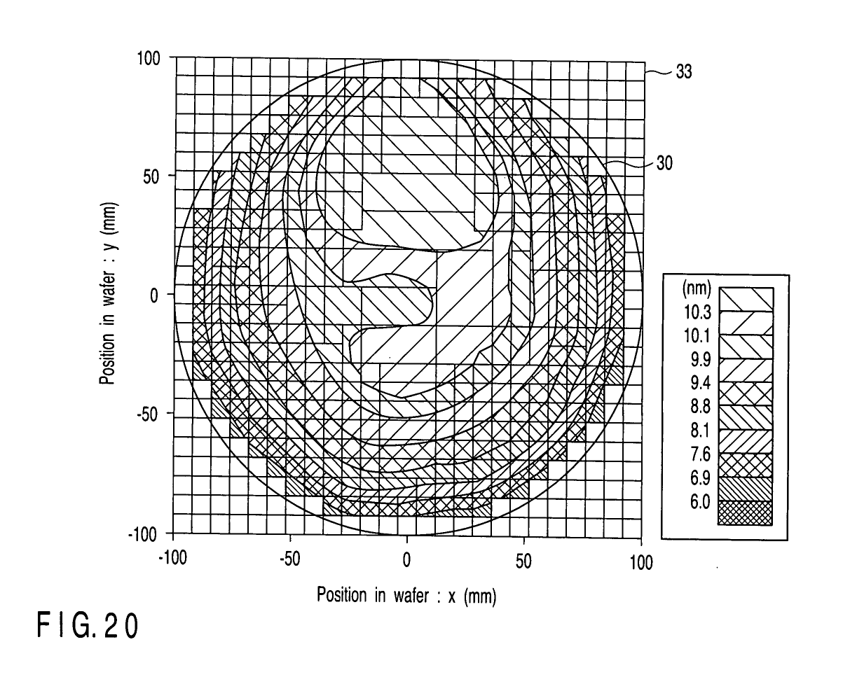

(d) At step S114, the common mesh data generator 14 shown in FIG. 1 represents each performance of each process step by using the common mesh 33 depicted in FIG. 18, thereby generating common mesh data as shown in FIGS. 19 to 20.

(e) At step S115, the predicting section 15 shown in FIG. 1 performs a through simulation using the common mesh data depicted in FIGS. 19 to 21 as input data, and predicts a comprehensive performance (a result of the through simulation) of a final product which has been processed through the series of process steps from steps S1 to S3 illustrated in FIG. 2 with regard to every region divided by the common mesh 33, as shown in FIG. 25. The comprehensive performance of the final product depicted in FIG. 25 is stored in the performance storage section 23. Further, the output device 4 appropriately outputs and displays a performance of interest.

(f) At step S116, the deciding section 16 shown in FIG. 1 decides whether the entire region in the wafer 30 satisfies the specification value based on the comprehensive performance of the final product depicted in FIG. 25. If it is decided that the entire region in the wafer 30 satisfies the specification value, the processing is completed. On the other hand, if there is a region which does not satisfy the specification value in the regions divided by the common mesh 33, the process advances to step S117.

(g) At step S117, the correcting section 17 shown in FIG. 1 performs sensitivity analysis based on the comprehensive performance of the final product shown in FIG. 25, and extracts parameters of the process conditions having a higher influence to improve the performance. Moreover, the correcting section 17 corrects/updates the process conditions stored in the process condition storage section 21.

(h) At step S118, the threshold setting section 18 shown in FIG. 1 resets the threshold value to be relaxed with respect to a region having an enough margin in the wafer 30 since a prediction accuracy of the region can be lowered and resets the threshold value to be tightened with respect to a critical region in the wafer 30 since a high prediction accuracy is required in the region based on the comprehensive performance of the final product depicted in FIG. 25, and feeds back and updates the threshold values stored in the threshold storage section 22.

(i) At step S119, the uniform mesh data generator 11 shown in FIG. 1 generates new uniform mesh data based on the process conditions corrected at step S117 like the procedure of step S111. At step S120, the non-uniform mesh generator 12 generates a new non-uniform mesh by using the new threshold fed back at step S118.

(j) At step S121, the common mesh generator 13 superimposes the new non-uniform mesh generated at step S119 to generate a new common mesh 33x as shown in FIG. 27. At step S121, the common mesh data generator 14 shown in FIG. 1 uses the new common mesh 33x depicted in FIG. 27 to generate new common mesh data as shown in FIGS. 28 to 30.

(k) At step S122, the predicting section 15 shown in FIG. 1 performs a through simulation on the new common mesh data depicted in FIGS. 28 to 30 being used as input data to predict a new comprehensive performance as illustrated in FIGS. 31 and 32.

(l) At step S124, the deciding section 16 shown in FIG. 1 decides whether the entire region in the wafer 30 satisfies the specification value. If the entire region in the wafer 30 satisfies the specification value, the processing is completed. On the other hand, if any region in the wafer 30 does not satisfy the specification value, the process returns to the procedure of step S117. Repeating the processing until the entire region in the wafer satisfies the specification value in this manner can acquire optimum process conditions.

According to the performance predicting method of the embodiment of the present invention, since common mesh data as shown in FIGS. 19 to 21 are used as input data in the in-plane characteristics distribution simulation of the wafer, unit regions as calculation objects can be reduced as compared with in the case where uniform mesh data as illustrated in FIGS. 4 to 6 are used as input data. Therefore, the calculation amount/calculation time can be reduced.

Additionally, feedback is performed from the comprehensive performance (the through simulation result) predicted by the predicting section 15 to optimize the division method (mesh areas) of the non-uniform meshes 32x, 32y and 32z, thereby improving a speed and accuracy of the simulation.

It is to be noted that the wafer 30 being processed from steps S119 to S124 may be the same wafer as the wafer 30 processed from steps S111 to S118, or it may be any other wafer, e.g., another wafer in the same lot, a wafer in another lot, or the like.

Based on a program (a performance prediction program) having an algorithm equivalent to that shown in FIG. 33, the performance prediction apparatus depicted in FIG. 1 can be controlled to execute the series of procedures illustrated in FIG. 33 including: (a) a procedure in which the uniform mesh data generator 11 divides the wafer surface by the uniform mesh to predict and generate uniform mesh data of each of the series of process steps; (b) a procedure in which the non-uniform mesh generator 12 generates the non-uniform mesh which non-uniformly divides the wafer surface based on the uniform mesh data with respect to each of the series of process steps; (c) a procedure in which the common mesh generator 13 superimposes the non-uniform meshes to select the smallest mesh in the non-uniform meshes as the common mesh in every region in the wafer; (d) a procedure in which the common mesh data generator 14 represents the performance of each of the series of process steps by using the common mesh; (e) a procedure in which the predicting section 15 uses the common mesh data to predict the comprehensive performance after the series of process steps in every region divided by the common mesh; (f) a procedure in which the correcting section 17 corrects the process conditions based on the predicted comprehensive performance; and others.

The program may be stored in the program storage device 6 of the computer system constituting the performance prediction apparatus depicted in FIG. 1. Alternatively, the program can be stored in a computer-readable recording medium and loaded to the program storage device 6 in the performance prediction apparatus by reading the recording medium, the series of procedures according to the present invention can be executed.

Here, the “computer-readable recording medium” includes a medium in which a program can be recorded there, e.g., an external memory device of a computer, a semiconductor memory, a magnetic disk, an optical disk, a magneto optical disk, a magnetic tape or the like. Specifically, a flexible disk, a CD-ROM, an MO disk and others are included in the “computer-readable recording medium”. For example, a main body of the performance prediction apparatus can be configured to include a flexible disk device (a flexible disk drive) and/or an optical disk device (an optical disk drive) as build-in devices or externally connected devices. A flexible disk is inserted into the flexible disk drive or a CD-ROM is inserted into the optical disk drive from an inserting port thereof, and a predetermined read operation is carried out, thereby installing a program stored in these recording mediums to the program storage device 6 constituting the performance prediction apparatus. Furthermore, with connecting an appropriate drive device, ROM or a magnetic tape device can be used. Moreover, the program can be stored in the program storage device 6 through an information processing network such as Internet.

A manufacturing method of a semiconductor integrated circuit (an LSI) according to an embodiment of the present invention will now be described with reference to a flowchart of FIG. 34. It is to be noted that a manufacturing method of a semiconductor device being described below is just an example, and it goes without saying that the present invention can be realized by other various manufacturing methods including modifications of the following manufacturing method.

(a) First, at designing step S100, electrical characteristics of elements constituting a LSI circuit are obtained through a process simulation, a lithography simulation or a device simulation. An electrical simulation of the LSI circuit is executed by using the electrical characteristics of the elements. Here, the performance prediction apparatus shown in FIG. 1 performs an in-plane characteristics distribution simulation to predict a comprehensive performance of a final product which has been processed through a series of procedures of a chip manufacturing process described later at step S300 similar to the procedures from step S111 to S124 shown in FIG. 33. Furthermore, process conditions are corrected to have optimum values based on the predicted comprehensive performance of the final product by the performance prediction apparatus shown in FIG. 1. Layout data of a design pattern (design data) corresponding to the corrected process conditions is generated.

(b) Then, at step S200, the layout data generated at step S100 is converted into drawing data. Based on the drawing data, a pattern generator (PG) or the like is used to generate a photomask for each layer corresponding to each stage of the LSI manufacturing process, and a set of photomasks is provided.

(c) In a front-end process (a wafer process) at step S302, a series of process steps such as an oxidization process at step S310, a resist coating process at step S311, a photolithography process at step S312, an ion implantation process at step S313, a heat treatment process at step S314 and others are repeatedly executed by using a corresponding group of semiconductor manufacturing equipments based on the process conditions corrected/optimized at step S100, thereby processing the wafer. However, if an actual performance of the wafer processed through the series of process steps in step S302 is found to be deviated from the target value set at step S100, then the in-plain characteristic distribution simulation is performed again using the actual performance data, as shown in steps S111 to S124. Results of the simulation is used to optimize process conditions of following process steps, thereby performing feed forward control of the process. When the series of process steps are finished, the process advances to step S303.

(d) At step S303, a back-end process (a wiring process) to form wirings on the wafer surface is executed. In the back-end process, a series of process steps such as a chemical vapor deposition (CVD) process at step S315, a resist coating process at step S316, a photolithography process at step S317, an etching process at step S318, a metal deposition process at step S319 and others are repeatedly executed by using a corresponding group of semiconductor manufacturing equipments based on the process conditions corrected/optimized at step S100, thereby processing the wafer. However, if an actual performance of the wafer processed through the series of process steps in step S303 is found to be deviated from the target value set at step S100, then the in-plain characteristic distribution simulation is performed again using the actual performance data, as shown in steps S111 to S124. Results of the simulation is used to optimize process conditions of following process steps, thereby performing feed forward control of the process. After forming a multilevel wiring structure on the wafer through the series of process steps, the process advances to step S320.

(e) At step S320, the wafer is divided into a plurality of chips with a predetermined chip size by a dicing apparatus such as a diamond saw. Then, the chip is mounted on a packaging material made of, such as a metal or ceramics, an electrode pad on the chip is connected with a lead of a lead frame through a gold wire, for example, and then a necessary package assembling process such as resin molding is carried out. At step 400, the semiconductor integrated circuit is brought to completion through predetermined testings, such as an electric characteristic testing related to performances and functions of the semiconductor integrated circuit, an inspection of a lead shape dimensions, a reliability test and others. At step S500, the semiconductor integrated circuit which has passed the above-described steps is packed to be protected against moisture, electrostatic electricity and others and then shipped.

As described above, according to the manufacturing method of the semiconductor device of the embodiment of the present invention, an amount of calculation and/or a calculation time can be reduced in an in-plane characteristics distribution simulation of the wafer included in the designing process at step S100. At the same time, a saved capacity of the performance prediction apparatus corresponding to the saved calculation amount can be exploited to improve an accuracy of the in-plane characteristics distribution simulation of the wafer. Therefore, as the entire semiconductor manufacturing process, a yield can be improved in an earlier stage of the production. Furthermore, at step S300, since the processing is executed under the process conditions corrected to have optimum values, a semiconductor device having reduced variation among lots and/or within a wafer can be manufactured.

Although the present invention has been described with reference to the foregoing embodiment, it should not be understood that the description and the drawings forming a part of this disclosure restrict the present invention. Various alternative modes, embodiments and operating techniques will become apparent to those skilled in the art based on this disclosure. For example, the uniform mesh data generator 11 shown in FIG. 1 divides the wafer surface 30 in each process step by using the same uniform mesh 31 as depicted in FIGS. 4 to 6, but the wafer surface 30 in each process step may be divided by using uniform meshes having different mesh sizes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A performance prediction apparatus comprising:
a uniform mesh data generator generating uniform mesh data by dividing a wafer surface using a uniform mesh to predict an in-plane characteristics distribution of performance with respect to each of a series of process steps;
a non-uniform mesh generator generating a non-uniform mesh which non-uniformly divides the wafer surface by combining a plurality of element meshes in the uniform mesh based on the uniform mesh data and predetermined threshold values with respect to each of the series of process steps;
a common mesh generator generating a common mesh by superimposing the plurality of non-uniform meshes and selecting a minimum mesh from the plurality of non-uniform meshes for every region in the wafer;
a common mesh data generator generating common mesh data by representing the in-plane characteristics distribution of performance with regard to each of the series of process steps using the common mesh; and
a predicting section predicting a comprehensive performance, which is a performance after processing the series of process steps, for every region divided by the common mesh based on the plurality of the common mesh data.

2. The performance prediction apparatus according to claim 1, wherein the non-uniform mesh generator generates the non-uniform mesh to be large in a region where the in-plane characteristics distribution moderately changes and to be small in a region where the in-plane characteristics distribution drastically changes.

3. The performance prediction apparatus according to claim 2, wherein the non-uniform mesh generator further generates a new non-uniform mesh by further combining the non-uniform mesh larger and/or further dividing the non-uniform mesh smaller based on the predicted comprehensive performance.

4. The performance prediction apparatus according to claim 2, wherein the non-uniform mesh generator statistically decides whether combining of the plurality of element meshes is possible or not based on a distribution function of data included in the combined mesh generated from distribution functions of data included in each of element meshes being combined, thereby automatically generating the non-uniform mesh.

5. The performance prediction apparatus according to claim 2, further comprising a deciding section to decide whether the predicted comprehensive performance satisfies a predetermined specification value.

6. The performance prediction apparatus according to claim 2, further comprising a correcting section to correct the process conditions based on the predicted comprehensive performance.

7. The performance prediction apparatus according to claim 6, wherein the deciding section further predicts a new comprehensive performance based on the corrected process conditions and decides whether the new comprehensive performance satisfies a predetermined specification value.

8. The performance prediction apparatus according to claim 1, wherein the non-uniform mesh generator further generates a new non-uniform mesh by further combining the non-uniform mesh larger and/or further dividing the non-uniform mesh smaller based on the predicted comprehensive performance.

9. The performance prediction apparatus according to claim 1, wherein the non-uniform mesh generator statistically decides whether combining of the plurality of element meshes is possible or not based on a distribution function of data included in the combined mesh generated from distribution functions of data included in each of element meshes being combined, thereby automatically generating the non-uniform mesh.

10. The performance prediction apparatus according to claim 1, further comprising a deciding section to decide whether the predicted comprehensive performance satisfies a predetermined specification value.

11. The performance prediction apparatus according to claim 1, further comprising a correcting section to correct the process conditions based on the predicted comprehensive performance.

12. The performance prediction apparatus according to claim 11, wherein the deciding section further predicts a new comprehensive performance based on the corrected process conditions and decides whether the new comprehensive performance satisfies a predetermined specification value.

13. A performance predicting method comprising:
generating uniform mesh data by dividing a wafer surface using a uniform mesh and predicting an in-plane characteristics distribution of performance with respect to each of a series of process steps;
generating a non-uniform mesh which non-uniformly divides the wafer surface by combining a plurality of element meshes in the uniform mesh based on the uniform mesh data and predetermined threshold values with respect to each of the series of process steps;
generating a common mesh by superimposing the plurality of non-uniform meshes and selecting a mesh having a minimum size from the plurality of non-uniform meshes for every region in the wafer;
generating a common mesh data by representing the in-plane characteristics distribution of performance of each of the series of process steps using the common mesh; and
predicting a comprehensive performance, which is a performance after processing through the series of process steps, for every region divided by the common mesh based on the common mesh data.

14. The performance prediction method according to claim 13, wherein generating the non-uniform mesh is to generate the non-uniform mesh to be large in a region where the in-plane characteristics distribution moderately changes and to be small in a region where the in-plane characteristics distribution drastically changes.

15. The performance prediction apparatus according to claim 13, wherein generating the non-uniform mesh further generates a new non-uniform mesh by further combining the non-uniform mesh larger and/or further dividing the non-uniform mesh smaller based on the predicted comprehensive performance.

16. The performance predicting method according to claim 13, wherein generating the non-uniform mesh further comprises:
selecting a starting mesh for combining;
selecting a candidate mesh for combining which is an element mesh having a minimum difference in an average value of data in the mesh out of element meshes adjacent to the starting mesh;
statistically testing a distribution function of data included in the starting mesh and a distribution function of a combined mesh having data of both the candidate mesh and the starting mesh as elements;
deciding whether the candidate mesh can be combined with the starting mesh based on the testing; and
automatically generating a non-uniform mesh based on the deciding.

17. The performance prediction method according to claim 13, further comprising deciding whether the predicted comprehensive performance satisfies a predetermined specification value.

18. The performance prediction method according to claim 13, further comprising correcting the process conditions based on the predicted comprehensive performance.

19. The performance prediction method according to claim 18, further comprising:
predicting a new comprehensive performance based on the corrected process conditions; and
deciding whether the new comprehensive performance satisfies a predetermined specification value.

20. A manufacturing method of a semiconductor device comprising:
using a performance prediction apparatus, to generate uniform mesh data by dividing a wafer surface using a uniform mesh and predicting an in-plane characteristics distribution of performance with respect to each of a series of process steps, to generate a non-uniform mesh which non-uniformly divides the wafer surface by combining a plurality of element meshes in the uniform mesh based on the uniform mesh data and predetermined threshold values with respect to each of the series of process steps, to generate a common mesh by superimposing the plurality of non-uniform meshes and selecting a mesh having a minimum size from the plurality of non-uniform meshes for every region in the wafer, to generate a common mesh data by representing the in-plane characteristics distribution of performance of each of the series of process steps using the common mesh, and to predict a comprehensive performance, which is a performance after processing through the series of process steps, for every region divided by the common mesh based on the common mesh data;
correcting process conditions of the series of process steps based on the comprehensive performance predicted by the performance prediction apparatus; and
executing the series of process steps according to the corrected process conditions using a corresponding group of semiconductor manufacturing equipments to process a wafer.
